(19) United States
(12) Patent Application Publication
(10) Pub. No.: US 2009/0267206 A1
(43) Pub. Date: Oct. 29, 2009

(54) STACKED SEMICONDUCTOR PACKAGE

(75) Inventors: YING-CHENG WU, Tu-Cheng (TW); TE-CHUN CHOU, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/192,083

(22) Filed: Aug. 14, 2008

(30) Foreign Application Priority Data
Apr. 28, 2008 (CN) 200810301349.3

(51) Int. Cl. H01L 23/488

(52) U.S. Cl. 257/686; 257/E23.023

(57) ABSTRACT

A stacked semiconductor package includes a circuit board with a number of pads disposed thereon, and a number of package units stacked on the circuit board. Each of the package units includes a substrate, a chip, an anisotropic conductive layer, and a number of conductive elements. The substrate has a first surface facing to the circuit board and a second surface opposite to the first surface, both of the first surface and the second surface have a number of pads disposed thereon. The chip is disposed on the substrate and electrically connected with the substrate. The anisotropic conductive layer is disposed between the substrate and the chip, and is capable of fixing the chip on the substrate. The conductive elements electrically connect the pads on the first surface of the substrate with the pads on the second surface of an adjacent substrate and the pads on the circuit board.

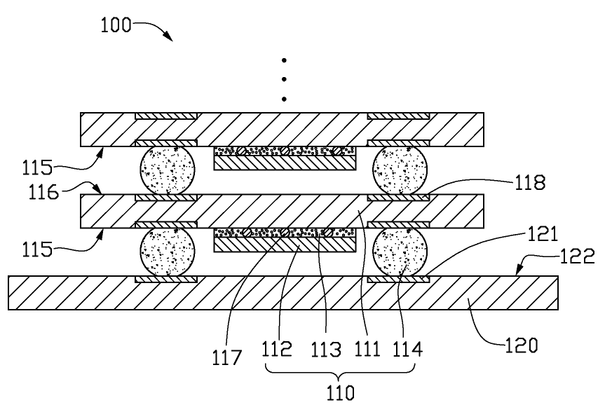

### BACKGROUND

1. Technical Field

The present invention relates to semiconductor packages and, particularly, to a stacked semiconductor package with multiple integrally packaged chips.

2. Description of the Related Art

In accordance with the trend of miniaturizing electronic apparatuses, attempts have been made to achieve high density of semiconductor chips assembled on a circuit board. In a typical electronic device, semiconductor chips are usually packed in semiconductor packages first before being assembled on a circuit board. However, each semiconductor package usually only pack one semiconductor chip therein, and the number of the semiconductor packages to be mounted on the circuit board is usually very large. As a result, the circuit boards would require relatively large sizes, which leads to bulky the electronic devices.

What is needed, therefore, is a stacked semiconductor package with multiple integrally packaged chips to overcome the above-described problem.

### SUMMARY

In an exemplary embodiment, a stacked semiconductor package includes a circuit board with a number of pads disposed thereon, and a number of package units stacked on the circuit board. Each of the package units includes a substrate, a chip, an anisotropic conductive layer, and a number of conductive elements. The substrate has a first surface facing to the circuit board and a second surface opposite to the first surface, both of the first surface and the second surface have a number of pads disposed thereon respectively. The chip is disposed on the substrate and electrically connected with the substrate. The anisotropic conductive layer is disposed between the substrate and the chip, and is capable of fixing the chip on the substrate. The conductive elements are configured for electrically connecting one of the pads on the first surface of the substrate with one pad selected form the group consisting of one of the pads on the second surface of an adjacent substrate and one of the pads on the circuit board.

### BRIEF DESCRIPTION OF THE DRAWING

Many aspects of the present stacked semiconductor package can be better understood with reference to the accompanying drawing. The components in the drawing are not necessarily drawn to scale, the emphasis instead being placed upon clearly illustrating the principles of the present stacked semiconductor package.

The drawing is a cross-sectional view of a stacked semiconductor package according to an exemplary embodiment.

### DETAILED DESCRIPTION OF THE EMBODIMENTS

Embodiments of the present invention will now be described in detail below, with reference to the accompanying drawing.

Referring to drawing, a stacked semiconductor package 100, according to an exemplary embodiment, is shown. The package 100 includes a circuit board 120 and a number of package units 110 stacked upon the circuit board. For the convenience of explanation, one package unit 110 is to be explained, as an example, in detail.

In the present embodiment, the circuit board 120 is a printed circuit board laminate composed of multiple layers of non-conductive material and conductive traces, each conductive trace being sandwiched between two layers of non-conductive material, together to form a rigid planar structure. A number of pads 121 reside on a surface 122 of the circuit board 120.

The package units 110 are stacked on the circuit board 120 one upon another. Each package unit 110 includes a substrate 111, a chip 112, an anisotropic conductive layer 113 disposed between the substrate 111 and the chip 112, and a number of conductive elements 114.

The substrate 111 can be made of plastic or ceramic with circuit therein. The substrate 111 includes a first surface 115 facing to the circuit board 120 and a second surface 116 opposite to the first surface 115. The first surface 115 and the second surface 116 both have a number of pads 118 disposed thereon. The pads 118 are disposed surrounding the chip 112.

In the present embodiment, the chip 112 is disposed on the first surface 115 of the substrate 111 with the anisotropic conductive layer 113 disposed there between. The chip 112 is fixed on the substrate 111 by the anisotropic conductive layer 113. The anisotropic conductive layer 113 can be configured with a conductive direction perpendicular to the first surface 115 for electrically connecting the substrate 111 and the chip 112. As a result, the substrate 111 and the chip 112 can be fixed and electrically connected with only one component. In the present embodiment, the anisotropic conductive layer 113 is disposed with a conductive direction parallel to the first surface 115 for only fixing the chip on the substrate 111, and the chip 112 also has conductive protrusions 117 for electrically connecting with the substrate 111. It is understood that the chip 112 can also be disposed on the second surface 116 of the substrate 111.

The anisotropic conductive layer 113 can be made of anisotropic conductive adhesives.

The conductive elements 114 are disposed on the first surface 115 of the substrate 111 for forming electrically connection among the substrates 111 of the package units 110 and the circuit board 120. To be specific, the conductive elements 114 of the package unit 110, the nearest unit to the circuit board 120, are configured for electrically connecting the corresponding substrate 111 with the circuit board 120. The conductive elements 114 of other package units 110 are configured for electrically connecting two adjacent substrates 111. In the present embodiment, the conductive elements 114 are solder balls. The solder balls can be leadless solder balls or lead-tin alloys balls.

While certain embodiments have been described and exemplified above, various other embodiments will be apparent to those skilled in the art from the foregoing disclosure. The present invention is not limited to the particular embodiments described and exemplified, and the embodiments are capable of considerable variation and modification without departure from the scope of the appended claims.

What is claimed is:

1. A stacked semiconductor package comprising:
a circuit board with a plurality of pads disposed thereon; and
a plurality of package units stacked on the circuit board, each of the package units comprising:
a substrate having a first surface facing to the circuit board and a second surface opposite to the first surface, both of the first surface and the second surface having a plurality of pads disposed thereon respectively;
a chip disposed on the substrate and electrically connected with the substrate;
an anisotropic conductive layer disposed between the substrate and the chip and capable of fixing the chip on the substrate; and
a plurality of conductive elements, each conductive element being configured for electrically connecting one of the pads on the first surface of the substrate with one pad selected form the group consisting of one of the pads on the second surface of an adjacent substrate and one of the pads on the circuit board.

2. The stacked semiconductor package as claimed in claim 1, wherein the anisotropic conductive layer is made of anisotropic conductive adhesives.

3. The stacked semiconductor package as claimed in claim 1, wherein the anisotropic conductive layer is disposed with a conductive direction perpendicular to the first surface for electrically connecting the substrate and the chip.

4. The stacked semiconductor package as claimed in claim 1, wherein the anisotropic conductive layer is disposed with a conductive direction parallel to the first surface only for fixing the substrate and the chip.

5. The stacked semiconductor package as claimed in claim 1, wherein the conductive elements are solder balls.

6. The stacked semiconductor package as claimed in claim 5, wherein the solder balls are leadless solder balls.

7. The stacked semiconductor package as claimed in claim 5, wherein the solder balls are lead-tin alloys balls.

8. The stacked semiconductor package as claimed in claim 1, wherein the chip has a plurality of conductive protrusions for electrically connecting with the substrate.

9. The stacked semiconductor package as claimed in claim 1, wherein the substrate is made of a material selected from the group consisting of plastic and ceramic.
